(19) United States
(12) Patent Application Publication
(10) Pub. No.: US 2011/0186542 A1
(43) Pub. Date: Aug. 4, 2011

(54) SLURRY CONTAINING MULTI-OXIDIZER AND MIXED NANO-ABRASIVES FOR TUNGSTEN CMP

(75) Inventors: Yuzhuo LI, Norwood, NY (US); Changxue WANG, Potsdam, NY (US)

(73) Assignee: ASPT, INC., Northbrook, IL (US)

(21) Appl. No.: 13/084,024

(22) Filed: Apr. 11, 2011

Related U.S. Application Data
(63) Continuation of application No. 12/220,958, filed on Jul. 30, 2008.

(51) Int. Cl. H05K 3/00; C09K 13/00; C23F 1/00; C23F 1/26; C23F 1/30; C23F 1/38; C23F 1/40; B82Y 30/00

(52) U.S. Cl. 216/13; 252/79.1; 216/53; 977/773

(57) ABSTRACT

A chemical mechanical polishing slurry containing multiple oxidizers and nano abrasive particles (including engineered nano diamond particles) suitable for polishing multilayer substrate with tungsten and Ti/TiN barrier layers. The slurry contains no metallic catalyst and has low total abrasive particle content. The absence of metal ions can be advantageous for certain applications as certain metal ions may present contamination issues. A low total abrasive content may also lower the total defect counts, reduce the slurry waste treatment burden, and simplify the post CMP clean process.

The present application claims priority under 35 U.S.C. §119(e) from Provisional Application No.: 60/952,933 filed Jul. 31, 2007, which is herein incorporated by reference.

### FIELD OF THE INVENTION

The present invention concerns a chemical mechanical polishing (CMP) slurry including two oxidizers, one of which is hydrogen peroxide. The resulting slurry is useful for polishing metal layers and thin-films associated with semiconductor manufacturing. More particularly, the present invention concerns a CMP slurry useful for polishing layers or films formed of tungsten in the presence of other barrier layers or thin films formed of titanium or titanium compounds such as titanium nitride.

### BACKGROUND OF THE INVENTION

Integrated circuits are made up of millions of active devices formed in or on a silicon substrate. The active devices, which are initially isolated from one another, are united to form functional circuits and components. The devices are interconnected through the use of well-known multilevel interconnections. Interconnection structures normally have a first layer of metallization, an interconnection layer, a second level of metallization, and sometimes a third and subsequent levels of metallization. Interlevel dielectrics such as doped and undoped silicon dioxide (SiO₂) are used to electrically isolate the different levels of metallization in a silicon substrate or well. The electrical connections between different interconnection levels are made through the use of metallized vias and in particular tungsten vias. In a similar manner, metal contacts are used to form electrical connections between interconnection levels and devices formed in a well. The metal vias and contacts are generally filled with tungsten and generally employ an adhesion layer such as titanium nitride (TiN) and/or titanium to adhere a metal layer such as a tungsten metal layer to SiO₂.

In one semiconductor manufacturing process, metallized vias or contacts are formed by a blanket tungsten deposition followed by a chemical mechanical polish (CMP) step. In a typical process, via holes are etched through an interlevel dielectric (ILD) to interconnection lines or to a semiconductor substrate. Next, a thin adhesion layer such as titanium nitride and/or titanium is generally formed over the ILD and is directed into the etched via hole. Then, a tungsten film is blanket deposited over the adhesion layer and into the via. The deposition is continued until the via hole is filled with tungsten. Finally, the excess tungsten is removed by chemical mechanical polishing (CMP) to form metal vias.

In a typical chemical mechanical polishing process, the substrate is placed in direct contact with a rotating polishing pad. A carrier applies pressure against the backside of the substrate. During the polishing process, the pad and table are rotated while a downward force is maintained against the substrate back. An abrasive and chemically reactive solution, commonly referred to as a “slurry” is deposited onto the pad during polishing. The slurry initiates the polishing process by chemically reacting with the film being polished. The polishing process is facilitated by the rotational movement of the pad relative to the substrate as slurry is provided to the wafer/pad interface. Polishing is continued in this manner until the desired film on the insulator is removed.

The slurry composition is an important factor in the CMP step. Depending on the choice of the oxidizing agent, the abrasive, and other useful additives, the polishing slurry can be tailored to provide effective polishing of metal layers at desired polishing rates while minimizing surface imperfections, defects, corrosion, and erosion of oxide in areas with tungsten vias. Furthermore, the polishing slurry may be used to provide controlled polishing selectivities to other thin-film materials used in current integrated circuit technology such as titanium, titanium nitride, oxide and the like.

Typically tungsten CMP polishing slurries contain abrasive particles, such as silica or alumina, suspended in an oxidizing, aqueous medium. To achieve high enough tungsten materials removal rate, the solid concentration of the slurry is usually in the range of 3 to 20 percent by weight (“wt. %”) when alumina and/or silica particles are used as the abrasives. However, such high abrasive concentrations are problematic in that they may cause significantly increased defect counts to the polished wafers. This in turn leads to higher costs and increased difficulty in treating the slurry waste.

The oxidizer agents for typical tungsten CMP polishing slurries are chosen from a wide range of ferricyanide compounds, ferric nitrate, mono-persulfate, di-persulfate, iodate, periodate, or hydrogen peroxide. Tungsten CMP polishing slurries may also include etching inhibitors, slurry suspension stabilizers, and pH buffer agents.

There are several patents on tungsten polishing slurries with single or mixed abrasives and single or multi oxidizers, which are briefly discussed below:

U.S. Pat. Nos. 5,340,370; 5,516,346; 5,836,806, 5,954,975; 6,178,585; and 6,375,552 report slurry with potassium ferricyanid as the single oxidizer and silica as the abrasive particles.

U.S. Pat. Nos. 5,527,423; 6,284,151; 6,294,105; and 6,355,565 refer to slurry comprising ferric nitrate as the single oxidizer and alumina or silica as the single abrasive particles.

With multi-oxidizer for the slurry, there are several combinations of two or even more kinds of oxidizers for tungsten and/or the titanium barrier layer.

U.S. Pat. Nos. 6,083,419 and 6,136,711 report slurry with ferric nitrate and hydrogen peroxide as the multi-oxidizers and silica as the single abrasive particles.

U.S. Pat. Nos. 5,958,288 and 6,068,787 report slurry with ferric nitrate and hydrogen peroxide (or mono-persulfate) as the multi-oxidizers and alumina or silica as the single abrasive particles.

U.S. Pat. No. 7,132,058 reports slurry with ferric nitrate and bromate (or chlorate) as the multi-oxidizers and alumina as the single abrasive particles.

U.S. Pat. Nos. 6,001,269 and 5,770,103 report slurry with iodate and hydrogen peroxide as the multi-oxidizers and alumina as the single abrasive particles (for W, Cu, and Al polishing).

U.S. Pat. No. 5,916,855 reports slurry with ferric nitrate and ammonium persulfate (APS) as the multi-oxidizers and alumina as the single abrasive particles.

U.S. Pat. Nos. 5,783489; 6,033,596; 6,039,891; and 6,316,366 report slurry with ammonium persulfate (APS) and hydrogen peroxide as the multi-oxidizer and alumina as the single abrasive particles designed for titanium, titanium nitride and alumina film polishing (not for tungsten layer polishing).

U.S. Pat. Nos. 6,117,783; 6,635,186; and 7,033,942 present slurry with APS and iodate, or APS and periodate, or APS and periodic acid, or hydrogen peroxide and hydroxylamine as multi-oxidizer and alumina as single abrasive particles for tungsten, titanium and titanium nitride polishing.

CMP slurries that are used to polish multiple metal layers in a single step typically exhibit a low polishing rate towards at least one of the metal layers. As a result, the polishing step is lengthened or operated at aggressive polishing conditions that can cause undesirable erosion of the SiO₂ layer and recessing of the metal vias and/or metal lines. Such recessing causes a non-planar via layer to be formed which impairs the ability to print high resolution lines during subsequent photolithography steps and can cause the formation of voids or open circuits in the formed metal interconnections. Additionally, recessing increases when over polishing is used to ensure complete removal of the tungsten, titanium, titanium nitride films across the surface of a wafer.

Thus, a need remains in the art for CMP slurries that can reliably polish a plurality of metal layers including a tungsten layer in an integrated circuit. Accordingly, it is an object of the present invention to provide such CMP slurries.

### SUMMARY OF THE INVENTION

The present invention is directed to a chemical mechanical polishing (CMP) slurry for polishing tungsten, titanium, and titanium nitride layers at acceptable rates. In addition, the CMP slurry of the invention provides a high tungsten to oxide insulator polishing selectivity while exhibiting low polishing selectivities of tungsten to titanium/titanium nitride.

Furthermore, in another embodiment, the present invention is directed to methods for using a CMP slurry to polish a plurality of metal layers in an integrated circuit. The integrated circuit includes at least one layer of tungsten and at least one layer of titanium or titanium nitride.

In another embodiment, the present invention is directed to a polishing kit. The kit includes a first package that contains hydrogen peroxide and a second package with a CMP slurry precursor that omits hydrogen peroxide. The CMP slurry precursor is combined with hydrogen peroxide prior to use to prepare the CMP slurry described above.

In a more preferred embodiment, the CMP slurry in the invention is in the form of an aqueous dispersion. The CMP slurry, in addition to hydrogen peroxide, further includes diamond particles, and a second oxidizer. Advantageously, the CMP slurry of the invention containing engineered nano diamond particles in very low concentration has been found to exhibit high tungsten removal rates, good surface quality, high planarization efficiency and low dishing as well as low erosion on the polished surfaces. These and other advantages will become more apparent from the detailed description of the invention.

### DETAILED DESCRIPTION OF THE PRESENT INVENTION

The present invention is related to a chemical mechanical polishing (CMP) slurry that comprises effective amounts of abrasive particles and of two oxidizers wherein one of the oxidizers is hydrogen peroxide. Reference to “effective amount” means any amount of the component that works in accordance with the present invention. The CMP slurry is used to polish at least one metal layer associated with a substrate that includes, but is not limited to, integrated circuits, thin films, multiple level semiconductors, and wafers. In particular, the CMP slurry of the invention has been found to exhibit excellent polishing selectivities when used to polish a substrate including layers of tungsten, titanium, titanium nitride layers via a single step, multiple metal layer chemical mechanical polishing process.

In accordance with the presented invention, diamond particles are used in the CMP slurry. The diamond particles can be used as the sole abrasive or mixed with other abrasive materials such as alumina or silica particles. The use of engineered nano diamond particles in a tungsten CMP slurry has not been reported up to date. The tungsten CMP slurry of the present invention preferably uses engineered nano diamond as the abrasive particles at very low concentrations in a multi-oxidizer aqueous medium. By reference to “aqueous” means that the medium comprises at least 50 wt. % water with the remainder being water-miscible organic solvents. Through the use of the engineered nano diamond particles, the CMP slurry provides the advantage of high removal rates, good surface quality, high planarization efficiency, low dishing and erosion for polishing tungsten surfaces with titanium and/or titanium nitride layers.

As stated above, the tungsten CMP slurry of present invention includes a two oxidizer system. The first oxidizer is hydrogen peroxide (i.e., H₂O₂). The hydrogen peroxide is preferably present in the slurry in an amount that ranges from about 0.1 wt. % to about 10 wt. % with from 3 wt. % to 5 wt. % being more preferred. As discussed further below, polishing experiments conducted with the CMP slurry of the invention have shown that an optimal concentration of hydrogen peroxide achieves the highest tungsten removal rate while the second oxidizer and abrasives are at a fixed concentration.

In accordance with the invention, the CMP slurry includes a second oxidizer. While any oxidizer know in the field can be used, in a preferred embodiment the second oxidizer is di-persulfate compound. An example of one particularly preferred di-persulfate compound is potassium persulfate (i.e., potassium peroxydisulfate) (“KPS”). The second oxidizer is preferably present in the CMP slurry in an amount ranging from about 0.1 to about 10 wt. %. In a more preferred embodiment of the invention, the second oxidizer is present in an amount ranging from 2.0 wt. % to no more than 4.0 wt. %. As discussed below, polishing experiments using the CMP slurry show that higher KPS concentrations does not result in higher tungsten removal rate while the first oxidizer and abrasive are at a fixed concentration.

The ratio of hydrogen peroxide to the secondary oxidizer is preferably ranges from 1:10 to 10:1 on a weight percent basis. In a more preferred embodiment, the ratio ranges 1:2 to 2:1. A significant deviation from such the recommended ratio reduces the synergistic effect between the two oxidizers.

The tungsten CMP slurry of the invention can include engineered nano diamonds as the sole abrasive or can include a mixture of nano diamonds with other secondary abrasives. The secondary abrasive is typically a metal oxide abrasive. Examples of metal oxide abrasive include, but are not limited to, alumina, titania, zirconia, germania, ceria and mixtures thereof. Other possible abrasives include garnet and diamond particles. Preferably, the CMP slurry of this invention includes from about 0.001 wt. % to about 0.05 wt. % engineered nano diamond particles alone or in combination with the other secondary abrasives. In a more preferred embodiment of the invention, the concentration of the abrasive particles is between 0.0025 wt. % to 0.01 wt. %.

The engineered nano diamond particles of the invention can come from a variety of source materials. Source materials for the diamond particles include, but are not limited to, monocrystalline diamond particles, polycrystalline diamond particles, natural diamond particles, and ultra-detonated diamond (UDD) particles.

Monocrystalline diamond particles tend to have more uniform surfaces and sharp edges. This is because the single crystal morphology and high degree of carbon-to-carbon bonds enable the particles to hold an edge for long periods of processing time. The abrasiveness of the monocrystalline diamond is also mainly governed by its particle size.

Polycrystalline diamond particle consists of thousands of micro crystallites bonded together. The unique microstructure of this species of diamond has many crystallites contained in the particle. In turn, these micro-crystals provide many points of contact at the crystal surface. The multitude of diamond points of angstrom (Å) size can produce a mirror-like finish on many surfaces and reduce friction. The polycrystalline diamonds are the only type of diamond that has self-sharpening properties. This is due to the ability of the polycrystalline structure to release an outer layer of dull micro crystallites thereby providing new sharp edges. As a result, polycrystalline diamond can lap and polish any material faster than any other abrasive while producing the smoothest, scratch free surface possible.

Natural diamond has cubic orientation. This orientation can be more beneficial in comparison to cubic octahedron structure of synthesized diamond.

Ultra-detonated diamond is essentially pure synthesized polycrystalline diamond. Because of its unique micro-structure (spherical) and functional hybrid carbon cover, it has become a popular diamond species when super finishes and purity are required The engineered nano diamond abrasive particles have average size (diameter) about 40 (nanometers) (“nm”). The nano diamond particle size distribution is also very narrow ranging from about 20 nm to about 60 nm. As discussed below, polishing experiments show that mixing colloidal silica particles with the engineered nano diamond particles in the CMP slurry reduces the effectiveness of the slurry. Thus, colloidal silica particles should be omitted from the CMP slurry (i.e., the slurry should be free of colloidal silica).

In a preferred embodiment of the invention, size of the diamond abrasive particles ranges from about 5 nm to about 50 nm. In a more preferred embodiment, the diamond abrasive particles range in size from about 12 nm to about 40 nm.

It is also desirable to maintain the pH of the tungsten CMP slurry within a range from about 2.0 to about 9.0. In a more preferred embodiment, the pH of the CMP slurry should range from 6.0 to 8.0. Maintaining the pH values of the CMP slurry facilitates control of the CMP process and avoids substrate polishing quality problems encountered at too low pH, e.g., less than 2. The pH value of the CMP slurry can be easily adjusted with conventional chemicals such nitric acid decrease pH or potassium hydroxide/ammonium hydroxide to increase pH.

In another embodiment of the invention, the mixture of oxidizers does not include a catalyst such as for example ferric ion. The advantage in omitting the catalysts includes a longer pot life time for the slurry and lower number of corrosion related defects.

In accordance with the invention, the CMP slurry can also include other conventional excipients used in CMP slurries. Examples of the other excipients include, but are limited to, surfactants, stabilizers and corrosion (etching) inhibitors.

The tungsten chemical mechanical polishing slurry of this invention has been found to have high tungsten polishing rate and high TiN polishing rate, relatively low Ti polishing rate and very low silicon dioxide polishing rate (˜15 Å/min). Thus the selectivity of W to TiN is relatively low (˜2:1) and selectivity of W to Ti is moderate (˜10:1) and selectivity of W to SiO₂ is very high (˜116:1). This allows relatively longer over polishing to clear the tungsten and titanium or titanium nitride barrier layers without too much oxide loss. The polishing experiments also show that the planarization efficiency of the tungsten slurry of this invention is very high (˜100% step height reduction efficiency) with good surface quality, and moderate dishing and low erosion.

This invention also relates to a chemical mechanical polishing slurry precursor kit. The precursor kit includes a first package containing hydrogen peroxide in an aqueous medium and a second package containing the CMP slurry precursor that includes abrasives and the second oxidizer in an aqueous medium. Prior to use, the contents of the two packages are combined to prepare the tungsten CMP slurry of the present invention. The kit is useful in that the shelf life of the tungsten slurry of this invention was tested and found to degrade over time. The reduction in shelf life is believed due to the instability of hydrogen peroxide which decomposes with time. Thus, to avoid possible CMP slurry degradation, a kit is provided to make the slurry right before polishing which is a two package system where a first package contains an effective amount of the first oxidizer (hydrogen peroxide) in an aqueous medium and a second package contains an aqueous medium with effective amounts of the second oxidizer (e.g., KPS) and other components such as the abrasives, and any optional additives.

The invention is further described by the following non-limiting examples which further illustrate the invention, and are not intended, nor should they be interpreted to, limit the scope of the invention.

### EXAMPLES

All polishing was performed using a Westech 372M polisher under 3 psi down pressure, 75/65 rpm table/carrier speed, 200 mL/min slurry flow rate with 1 psi back pressure. The engineered nano diamond particle sample was obtained from UK Abrasives with Batch Number DP1-IA45.

### Example 1

CMP polishing was performed with slurry of varying wt. % of diamond, varying wt. % of KPS at pH=6.0 without H₂O₂. The results showed that the tungsten removal rate (“MRR”) increases with diamond particle wt. % increase, higher KPS wt. % and gave a higher tungsten removal rate. However, overall tungsten removal rate was relatively low (for example, 500 angstroms per minute (“Å/min”) at 2 wt. % KPS and 0.04 wt. % diamond).

TABLE 1
KPS and abrasive concentration effect on
tungsten removal rate (without H₂O₂)

| KPS | Diamond | MRR |
|---|---|---|
| wt. % | wt. % | (Å/min) |
| 0.5 | 0.01 | 78 |
| | 0.02 | 85 |
| | 0.04 | 250 |
| 2.0 | 0 | 31 |
| | 0.01 | 246 |
| | 0.02 | 298 |
| | 0.04 | 500 |

### Example 2

CMP polishing was performed with a slurry of varying wt. % of diamond, varying wt. % of KPS, 1% H₂O₂ at pH=6.0. The results showed that tungsten removal rates are much higher at 0.01% and 0.02% diamond weight concentration with 2 wt. % KPS and 1% H₂O₂ (1320 Å/min and 1610 Å/min respectively) than without H₂O₂ 9246 Å/min and 298 Å/min respectively, from Table 1). The results also showed that with 1% H₂O₂, higher KPS wt. % does not give higher tungsten removal rate, but on the contrary, lead to lower removal rate.

TABLE 2
KPS and abrasive concentration effect on
tungsten removal rate (with 1% H₂O₂)

| KPS | Diamond | MRR |
|---|---|---|
| Wt. % | wt. % | (Å/min) |
| 2.0 | 0.01 | 1320 |
| 4.0 | | 663 |
| 2.0 | 0.02 | 1610 |
| 4.0 | | 1410 |

### Example 3

The effect of H₂O₂ on tungsten removal rate was investigated with slurry at varying wt. % of diamond, varying wt. % of H₂O₂, varying pH, with fixed 2 wt. % of KPS. The results showed that tungsten removal rates increased significantly with the increase of H₂O₂ wt. %, tungsten removal rate also increases slowly with diamond wt. % increase at both pH=3 and pH=6. It was further noticed from Table 3.1 and Table 3.2 that tungsten removal rates at different diamond wt. % and H₂O₂ wt. % are comparable at pH=3 and at pH=6, i.e. pH of the slurry does not significantly influence the tungsten removal rate. At 3% H₂O₂, 2% KPS, tungsten removal rates are at 2000 Å/min for all three low diamond concentration and surface qualities were very good (very low roughness).

TABLE 3.1
H₂O₂ effect on tungsten removal rate
(with 2% KPS) at pH = 3

| Diamond | H₂O₂ | MRR |
|---|---|---|
| wt. % | wt. % | (Å/min) |
| 0.01 | 0 | 289 |
| | 1 | 1100 |
| | 3 | 2270 |
| 0.02 | 0 | 363 |
| | 1 | 1650 |
| | 3 | 2430 |

TABLE 3.2
H₂O₂ effect on tungsten removal rate
(with 2% KPS) at pH = 6

| Diamond | H₂O₂ | MRR | Ra | Rq |
|---|---|---|---|---|
| wt. % | wt. % | (Å/min) | (nm) | (nm) |
| 0.01 | 0 | 246 | — | — |
| | 1 | 1320 | — | — |
| | 3 | 2110 | 0.33 | 0.41 |
| 0.02 | 0 | 298 | — | — |
| | 1 | 1610 | — | — |
| | 3 | 2360 | 0.30 | 0.38 |
| 0.04 | 0 | 500 | — | — |
| | 1 | 1820 | — | — |
| | 3 | 2650 | 0.34 | 0.43 |

### Example 4

The effect of pH on tungsten removal rate was investigated for the slurry at varying wt. % of diamond, varying pH, with fixed 2 wt. % of KPS but without H₂O₂ (Example 3 shows the pH effect for slurry with different H₂O₂ wt. %). The results showed that tungsten removal rates were comparable at three different diamond wt. % for all three pH values. Again, this showed the pH of the slurry does not influence the tungsten removal rate.

TABLE 4
pH effect on tungsten removal rate
(with 2% KPS) without H₂O₂

| | Diamond | MRR |
|---|---|---|
| pH | wt. % | (Å/min) |
| 3.0 | 0.01 | 289 |
| | 0.02 | 363 |
| 6.0 | 0.01 | 246 |
| | 0.02 | 298 |
| | 0.04 | 500 |
| 8.0 | 0.01 | 253 |
| | 0.02 | 307 |
| | 0.04 | 462 |

### Example 5

The effect of colloidal silica particles mixing with diamond particles on tungsten removal rate was investigated for slurry at varying wt. % of diamond, varying wt. % of silica, 4.0 wt. % KPS, 1.0 wt. % H₂O₂ at pH=6. The results showed that tungsten removal rates decrease significantly with the increase of silica wt. %. This shows that mixing colloidal silica particles to the engineered nano diamond particles in the slurry did not improve tungsten polishing performance. Hence, mixing silica with diamond particles for this slurry was not necessary and should in fact be avoided.

TABLE 5
Effect of mixing silica particles
on tungsten removal rate

| Diamond | Silica | MRR |
|---|---|---|
| wt. % | wt. % | (Å/min) |
| 0.01 | 0 | 663 |
| | 1 | 488 |
| | 3 | 328 |
| 0.02 | 0 | 1410 |
| | 1 | 439 |
| | 3 | 316 |

### Example 6

The effect of slurry shelf life on tungsten removal rate was investigated for slurry at 0.01 wt. % diamond, 2.0 wt. % KPS, 3.0 wt. % H₂O₂ at pH=6. The results show that tungsten removal rates decreased with shelf life time. At 36 hours of shelf life, the tungsten removal rate of this slurry dropped to about half of the removal rate of fresh slurry. This showed that preparing the slurry with second oxidizer (KPS) and abrasives, deionized (“DI”) water and other necessary additives (for example, acid or base for pH adjusting) for a package as the slurry precursor, and adding the first oxidizer (hydrogen peroxide) to the precursor to make the tungsten slurry just before polishing may be more appropriate to avoid removal rate degradation of the slurry.

TABLE 6
Effect of slurry shelf life on
tungsten removal rate

| Slurry Shelf | MRR |
|---|---|
| Life (Hours) | (Å/min) |
| 0 | 1560 |
| | 1740 |
| 4 | 1330 |
| 12 | 1170 |
| 36 | 899 |

### Example 7

The selectivity of removal rate of tungsten to that of titanium, titanium nitride and silicon dioxide was investigated for slurry at 0.01 wt. % diamond, 2.0 wt. % KPS, 3.0 wt. % H₂O₂ at pH=6 (same as in Example 6). The results showed that the slurry gives a high tungsten removal rate, high TiN removal rate, relative low Ti removal rate and very low silicon dioxide removal rate. This selectivity of W to TiN is relatively low (˜2:1) and selectivity of W to Ti is moderate (˜10:1) and selectivity of W to SiO₂ is very high (˜116:1). The low selectivity of W to TiN allowed the clearing of tungsten and TiN barrier layer in almost similar rate during over polishing and the high selectivity of W to silicon dioxide allow relatively longer over polishing to clear all overburden tungsten and barrier layers without significant loss of oxide dielectric layer.

TABLE 7
Selectivity of tungsten removal
rate to that of Ti, TiN, SiO₂

| | MRR |
|---|---|
| Wafer | (Å/min) |
| W | 1740 |
| Ti | 181 |
| TiN | 932 |
| Oxide | 15 |

### Example 8

The patterned wafer polishing was performed to investigate the planarization efficiency and dishing, erosion height for slurry at 0.01 wt. % diamond, 2.0 wt. % KPS, 3.0 wt. % H₂O₂ at pH=6 (same as in Example 6). The results showed that the slurry gives very high planarization efficiency (˜100% step height reduction efficiency), dishing height was moderate (973 Angstrom) and erosion height was low (˜500 Angstrom) for more than 30 seconds over polishing.

The results of these examples demonstrated that the tungsten CMP slurry in this invention including a first oxidizer and a second oxidizer was effective, over a wide range of pH values in polishing multiple layers of metallization in a single polishing step.

While the present invention has been described by means of specific embodiments, it will be understood that modifications may be made without departing from the spirit of the invention.

### INCORPORATION BY REFERENCE

Any foregoing applications and all documents cited therein or during their prosecution (“application cited documents”) and all documents cited or referenced in the application cited documents, and all documents cited or referenced herein (“herein cited documents”), and all documents cited or referenced in herein cited documents, together with any manufacturer's instructions, descriptions, product specifications, and product sheets for any products mentioned herein or in any document incorporated by reference herein, are hereby incorporated herein by reference, and may be employed in the practice of the invention.

We claim:

1. A polishing composition with selective metal polishing characteristics comprising an aqueous slurry including an effective amount of the following components:
a first oxidizer being hydrogen peroxide;
a second oxidizer being a persulfate compound; and
an abrasive particulate including diamond particles,
wherein the slurry has a pH value ranging from about 2 to about 9.

2. The polishing composition of claim 2, wherein the effective amount of the first and second oxidizers are each about 0.1 to about 10 percent by weight.

3. The polishing composition of claim 2, wherein the amount of the first oxidizer ranges from 1 to 3 percent by weight.

4. The polishing composition of claim 2, wherein the amount of the second oxidizer is no more than 4 percent by weight.

5. The polishing composition of claim 1, wherein the persulfate compound is potassium persulfate.

6. The polishing composition of claim 1, wherein the effective amount of abrasive particulate is about 0.001 to about 0.05 percent by weight.

7. The polishing composition of claim 6, wherein the diamond particles are engineered nano diamonds.

8. The polishing composition of claim 7, wherein the engineered nano diamonds range in size from 5 to 50 nanometers.

9. The polishing composition of claim 1, wherein the slurry has a pH value ranging from about 6 to about 8.

10. A method of polishing a substrate containing metal layers, which comprises:
providing a substrate in need of polishing, the substrate including at least one layer of tungsten and at least one layer of titanium or titanium nitride;
providing an aqueous slurry polishing composition including an effective amount of the following components,
a first oxidizer being hydrogen peroxide,
a second oxidizer being a persulfate compound, and
an abrasive particulate including diamond particles,
wherein the slurry has a pH value ranging from about 2 to about 9; and
polishing the substrate by the application of the slurry under pressure with a polishing pad for a sufficient amount of time.

11. The method of claim 10, wherein the substrate is formed from silicon dioxide and is selected from the group consisting of integrated circuits, thin films, multiple level semiconductors, and wafers.

12. The method of claim 10, wherein the effective amount of the first and second oxidizers are each about 0.1 to about 10 percent by weight.

13. The method of claim 11, wherein the amount of the first oxidizer ranges from 1 to 3 percent by weight.

14. The method of claim 11, wherein the amount of the second oxidizer is no more than 4 percent by weight.

15. The method of claim 10, wherein the persulfate compound is potassium persulfate.

16. The method of claim 10, wherein the effective amount of abrasive particulate is about 0.001 to about 0.05 percent by weight.

17. The method of claim 16, wherein the diamond particles are engineered nano diamonds.

18. The method of claim 17, wherein the engineered nano diamonds range in size from 5 to 50 nanometers.

19. The method of claim 10, wherein the slurry has a pH value ranging from about 6 to about 8.

20. A kit for preparing an aqueous slurry polishing composition comprising:
a first package containing an effective amount of a first oxidizer being hydrogen peroxide in an aqueous medium; and
a second package containing in an aqueous medium effective amounts of a second oxidizer being a persulfate compound and an abrasive particulate including diamond particles, wherein the aqueous medium of the first and second packages has a pH value ranging from about 2 to about 9.
